(19) United States
(12) Patent Application Publication
(10) Pub. No.: US 2026/0329196 A1
(43) Pub. Date: Oct. 22, 2026

(54) METHOD AND COMPUTING DEVICE FOR COMPENSATING FOR LIQUID-TRANSMITTED ACOUSTIC DISTURBANCE EXCITATIONS OF AN OPTICAL COMPONENT OF A LITHOGRAPHY SYSTEM, SAID OPTICAL COMPONENT BEING TEMPERATURE-CONTROLLED USING A LIQUID, COMPENSATION SYSTEM, LITHOGRAPHY SYSTEM, AND METHOD FOR PRODUCING A CONTROL DEVICE

(71) Applicant: Carl Zeiss SMT GmbH, Oberkochen (DE)

(72) Inventors: Luca Mettenleiter, Neresheim (DE); Matthias Fetzer, Stuttgart (DE)

(21) Appl. No.: 19/687,648

(22) Filed: May 26, 2026

Related U.S. Application Data
(63) Continuation of application No. PCT/EP2024/082378, filed on Nov. 14, 2024.

(30) Foreign Application Priority Data
Dec. 5, 2023 (DE) 102023212251.0

(51) Int. Cl. G03F 7/00; G02B 27/64

(52) U.S. Cl. CPC G03F 7/709; G02B 27/646; G03F 7/70141; G03F 7/70258; G03F 7/70508; G03F 7/70516; G03F 7/70525; G03F 7/70825; G03F 7/70891; G03F 7/70991

(57) ABSTRACT

The invention relates to a method for compensating for liquid-transmitted acoustic disturbance excitations of an optical component of a lithography system, said optical component being temperature-controlled using a liquid, wherein the disturbance excitations of the optical component, as a first optical component, are compensated for using a second optical component of the lithography system, said second optical component not being temperature-controlled using a liquid. The method has the steps of: a) receiving a first and second actual value of a position corresponding to the first and second optical component, and b) controlling the position of the second component to an adapted target value of the position of the second optical component, said target value being based on the initial target value of the position of the second optical component and the first actual value of the position of the first optical component. The invention relates to a method for compensating for liquid-transmitted acoustic disturbance excitations of an optical component of a lithography system, said optical component being temperature-controlled using a liquid, wherein the disturbance excitations of the optical component, as a first optical component, are compensated for using a second optical component of the lithography system, said second optical component not being temperature-controlled using a liquid. The method has the steps of: a) receiving a first and second actual value of a position corresponding to the first and second optical component, and b) controlling the position of the second component to an adapted target value of the position of the second optical component, said target value being based on the initial target value of the position of the second optical component and the first actual value of the position of the first optical component.

### CROSS-REFERENCE TO RELATED APPLICATIONS

This application is a continuation of and claims benefit under 35 U.S.C. § 120 from PCT application PCT/EP2024/082378, filed on Nov. 14, 2024, which claims priority from German patent application 10 2023 212 251.0, filed on Dec. 5, 2023. The entire contents of each of these earlier applications are incorporated herein by reference

### TECHNICAL FIELD

The present invention relates to a method and a computing device for compensating for liquid-transmitted acoustic disturbance excitations of an optical component of a lithography apparatus, said optical component being temperature-controlled using a liquid, to a compensation system and to a lithography apparatus having such a computing device, and to a method for producing controller equipment for controlling a position of an optical component of a lithography apparatus, said optical component being temperature-controlled using a liquid.

### BACKGROUND

Microlithography is used to produce microstructured structural elements, for example integrated circuits. The microlithography process is conducted with a lithography apparatus having an illumination system and a projection system. The image of a mask (reticle) illuminated by use of the illumination system is projected here by use of the projection system onto a substrate, for example a silicon wafer, which is coated with a light-sensitive layer (photoresist) and is arranged in the image plane of the projection system, in order to transfer the mask structure to the light-sensitive coating of the substrate.

In striving to achieve ever smaller structures in the production of integrated circuits, EUV lithography apparatuses that use light at a wavelength in the range of 0.1 nm to 30 nm, in particular 13.5 nm, are currently under development. Since most materials absorb light at this wavelength, such EUV lithography apparatuses require the use of reflective optical units, i.e. mirrors, instead of refractive optical units, i.e. lens elements, as used previously.

The demands on the accuracy and precision of the imaging properties of lithography apparatuses are constantly increasing. From a dynamic point of view, the influence of disturbance inputs on the movement of various component parts of the lithography apparatus must be minimized in this context. For example, very precise positioning of optical components, in particular mirrors, and mechanical components, in particular sensor frames, of the lithography apparatus is required. Dynamic disturbance excitations of optical and mechanical components may be produced, for example, by the movement of other component parts of the lithography apparatus. Furthermore, on account of increasing thermal requirements, it is necessary to cool optical and mechanical components of the lithography apparatus, in particular mirrors and sensor frames. Cooling requires a cooling device with cooling lines, through which a cooling liquid is transported to the component to be cooled. This leads to a further source of dynamic disturbance excitations in the form of acoustic disturbances. Acoustic disturbances are transmitted, for example as longitudinal waves, through the cooling liquid in the cooling lines to the component to be cooled.

### SUMMARY

Against this background, it is an aspect of the present invention to provide an improved method and an improved computing device for compensating for liquid-transmitted acoustic disturbance excitations of an optical component of a lithography apparatus, said optical component being temperature-controlled using a liquid.

According to a first aspect, a method for compensating for liquid-transmitted acoustic disturbance excitations of an optical component of a lithography apparatus is proposed, said optical component being temperature-controlled using a liquid. In this case, the disturbance excitations of the optical component, as a first optical component, are compensated for with the aid of a second optical component of the lithography apparatus, said second optical component not being temperature-controlled using a liquid. The method comprises the steps of:
a) receiving a first and second actual value of a position corresponding to the first and second optical components, and
b) controlling the position of the second optical component to an adapted target value of the position of the second optical component, said target value being based on an initial target value of the position of the second optical component and the first actual value of the position of the first optical component.

Consequently, the position of the second optical component is controlled to a target position that includes the actual position of the first optical component. A position error of the first optical component, which is temperature-controlled using a liquid, is thus forwarded to a control loop of the second optical component which is not temperature-controlled using a liquid. As a result, the control loop of the second optical component which is not temperature-controlled using a liquid corrects the position errors of both the first and the second optical component. The proposed control architecture thus makes it possible to at least partially compensate for a position error of the first optical component, which is temperature-controlled using a liquid, on account of liquid-transmitted acoustic disturbance excitations by controlling the position of the second optical component.

In particular, a position error of the first optical component can lead to an imaging error of the first optical component. This imaging error is also offset by the proposed position control of the second optical component, which changes the imaging property of the second optical component.

By way of example, the adapted target value of the position of the second optical component is a sum of the initial target value of the position of the second optical component and the first actual value of the position of the first optical component. The initial target value of the position of the second optical component is, in particular, a target value for the position of the second optical component, which target value corresponds to the desired value for the position of the second optical component in a case in which a position error of the first optical component is not also corrected or the position error of the first optical component is zero.

Acoustic disturbance excitations are transmitted via liquid sound waves (i.e., pressure waves or pressure fluctuations, e.g. longitudinal waves) of the liquid in the liquid lines to components which are temperature-controlled using a liquid, such as the first optical component. By way of example, the first optical component is mechanically connected to one or more liquid lines in order to transport the liquid to the first optical component and away from the first optical component. As a result, force is transmitted to the first optical component at the surfaces of the first optical component on which the pressure fluctuations are incident.

Acoustic disturbance excitations can be caused by flow-induced vibrations (FIV) of the liquid. Flow-induced vibrations are produced, for example, by pumps, valves, line diversions and line cross-sectional changes (so-called “FIV sources”). Acoustic disturbance excitations can also be transmitted to the liquid by virtue of mechanical vibrations of other component parts being transmitted via carrier elements of the liquid lines.

If pressure fluctuations of a liquid occur in a liquid line, which serves for controlling the temperature (e.g., cooling) of an optical component, the position of the optical component can be changed in an undesired manner by the acoustic disturbance excitations. This leads to an imaging error of the optical component and thus of the lithography apparatus. Position control of the first optical component which is temperature-controlled using a liquid can—in particular in the case of a conventional controller architecture13 lead to superimposition of the resonances of the disturbance excitation and the transfer function of the controller used.

Since the second optical component is not temperature-controlled using a liquid, the second optical component is not subject to any liquid-transmitted acoustic disturbance excitation. Consequently, the actuator system of the second optical component can advantageously be used to compensate for position changes of the first optical component indirectly (specifically by changing the position of the second optical component).

For example, the lithography apparatus is an EUV or a DUV lithography apparatus. EUV stands for “extreme ultraviolet” and refers to a wavelength of the operating light in the range from 0.1 nm to 30 nm, in particular 13.5 nm. Furthermore, DUV stands for “deep ultraviolet” and refers to a wavelength of the operating light between 30 nm and 250 nm.

The EUV or DUV lithography apparatus comprises an illumination system and a projection system. In particular, using the EUV or DUV lithography apparatus, the image of a mask (reticle) illuminated by use of the illumination system is projected by use of the projection system onto a substrate, for example a wafer and/or silicon wafer, which is coated with a light-sensitive layer (photoresist) and is arranged in the image plane of the projection system, in order to transfer the mask structure to the light-sensitive coating of the substrate.

The lithography apparatus has, for example, a temperature control device (e.g., cooling device) which comprises one or more liquid lines for transporting a temperature control liquid (e.g., cooling liquid, such as water) to the first optical component.

The first and/or second optical component is, for example, a mirror of the lithography apparatus. The first and/or second optical component is, for example, an optical component of a projection system of the lithography apparatus. In particular, the first and/or second optical component is a component that must be kept at an exact position with only small tolerances during operation of the lithography apparatus.

A cooling device of the lithography apparatus is configured, for example, to cool the first optical component of the lithography apparatus. By contrast, the second optical component is an optical component which is not temperature-controlled, e.g. is not cooled. The cooling device can also be configured, for example, to cool further optical and/or mechanical components of the lithography apparatus—with the exception of the second optical component. The cooling device serves in particular to avoid high temperatures and temperature fluctuations of the first optical component (and optionally of further components to be cooled). Especially mirrors of an EUV lithography apparatus (as an example of a first optical component) heat up as a result of absorption of the high-energy EUV radiation. High temperatures and temperature fluctuations in the mirror which are caused thereby and accompanying thermal deformations of the mirror may lead to wavefront aberrations and may hence adversely affect the imaging properties of the mirrors. Optical components of the lithography apparatus are actively cooled in order to prevent thermally induced deformations.

The temperature control device (e.g., cooling device) has, for example, a temperature control unit (e.g., cooling unit) for controlling the temperature (e.g., cooling) of the liquid. The temperature control device has one or more liquid lines for transporting the liquid. The liquid line(s) is/are made of metal, for example, such as stainless steel. The temperature control device also comprises one or more pumps for generating a required flow rate of the liquid in the line and one or more valves for controlling the flow through the line.

The temperature control device can be a cooling device for cooling the first optical component or else a heating device for heating the first optical component.

According to one embodiment of the first aspect, the method comprises a step of controlling the position of the first optical component to a first target value of the position of the first optical component on the basis of the first actual value.

In this embodiment, the position of the first optical component is also controlled—in addition to controlling the position of the second optical component. Since the first optical component is temperature-controlled using a liquid and is thus subject to acoustic disturbance excitations, a control error when controlling the position of the first optical component can be relatively large. The (e.g., remaining) control error of controlling the position of the first optical component is then at least partially compensated for by use of the adapted target variable when controlling the position of the second optical component.

According to a further embodiment of the first aspect, controlling the position of the first optical component comprises:
determining a first manipulated variable on the basis of a first deviation of the first actual value from the first target value, and
actuating first actuator equipment to position the first optical component on the basis of the first manipulated variable.

The position of the first optical component is thus controlled by use of feedback control. In particular, the first actual position is fed back for determining the first deviation.

By way of example, the first actuator equipment is configured to set the position of the first optical component in relation to six degrees of freedom of the first optical component. The six degrees of freedom comprise in particular three degrees of translation freedom (in three spatial directions which span a three-dimensional space) and three degrees of rotation freedom (with respect to a rotation about the three spatial directions).

According to a further embodiment of the first aspect, controlling the position of the second optical component comprises:
determining a second manipulated variable on the basis of a second deviation of the second actual value from the adapted target value, and
actuating second actuator equipment to position the second optical component on the basis of the second manipulated variable.

The position of the second optical component is thus controlled by use of feedback control. In particular, the second actual position is fed back for determining the second deviation.

By way of example, the second actuator equipment is configured to set the position of the second optical component in relation to six degrees of freedom of the second optical component. The six degrees of freedom comprise in particular three degrees of translation freedom (in three spatial directions which span a three-dimensional space) and three degrees of rotation freedom (with respect to a rotation about the three spatial directions).

The following relationships apply, for example, to controlling the position of the first and/or the second optical component. The first or the second manipulated variable is determined on the basis of an actual value/target value deviation of the position of the corresponding optical component. As a result, position control is possible on the basis of feedback of the measured current value (i.e., the first or second actual value) of the position of the corresponding optical component. The first or second actual value of the position of the corresponding optical component is measured, for example, and fed back to an input of corresponding position controller equipment.

By way of example, the first target value of the position of the first optical component and/or the initial target value of the position of the second optical component is/are a static value, such that the position of the corresponding optical component is controlled to a rest position corresponding to the static value. However, the first or initial target value of the position of the corresponding optical component can also change depending on the time, and so the aim of the corresponding control is for the position of the corresponding optical component to follow a predefined time-dependent path (trajectory).

The first or second deviation (that is to say the corresponding control deviation) is determined in particular by negatively supplying (subtracting) the first or second actual value to the first or adapted target value.

The first and/or second manipulated variable is determined in particular in such a way that the current position of the corresponding optical component (controlled variable) is adapted to the first or adapted target value (reference variable). The first or second manipulated variable is in particular a measure of a position change to be applied to the corresponding optical component by use of the first or second actuator equipment.

According to a further embodiment of the first aspect, the position of the first optical component is controlled in a first predetermined control frequency range which is different from a predetermined disturbance frequency range of the acoustic disturbance excitations of the first optical component.

As a result, the control frequency range in which the position of the first optical component is controlled can be arranged in a preset manner in a frequency range in which acoustic disturbance excitations are low and/or not present. Consequently, resonance transmissions of the disturbance excitation and transfer function of the controller can be avoided or reduced.

The fact that the first predetermined control frequency range is different from the predetermined disturbance frequency range means, for example, that the first predetermined control frequency range and the predetermined disturbance frequency range do not overlap, are disjoint and/or adjoin one another (e.g., directly).

By way of example, an upper cutoff frequency of the first predetermined control frequency range is less than or equal to a lower cutoff frequency of the predetermined disturbance frequency range.

By way of example, a lower cutoff frequency of the first predetermined control frequency range is greater than or equal to an upper cutoff frequency of the predetermined disturbance frequency range.

By way of example, the predetermined disturbance frequency range is 1 to 60 Hz, 60 to 150 Hz and/or 80 to 200 Hz.

By way of example, the first predetermined control frequency range is 60 to 120 Hz and the predetermined disturbance frequency range is 1 to 60 Hz. By way of example, the first predetermined control frequency range is 40 to 80 Hz and the predetermined disturbance frequency range is 80 to 200 Hz. By way of example, the first predetermined control frequency range is 1 to 40 Hz or 1 to 60 Hz and the predetermined disturbance frequency range is 60 to 150 Hz.

A main source of mechanical vibrations of the lithography apparatus is, for example, a mask holder (reticle stage) and a substrate holder (wafer stage) of the lithography apparatus. The mask holder is used to carry and move a mask to be imaged. Furthermore, the substrate holder is used to carry and move a substrate on which an image of the mask is imaged. Mechanical vibrations of the lithography apparatus can be transmitted via carrier elements to liquid lines for controlling the temperature (e.g., cooling) of the first optical component. Vibrations in the form of acoustic vibrations are transmitted to the first optical component via the liquid in the liquid lines. The disturbance excitations caused by the mask holder (reticle stage) and the substrate holder (wafer stage) have, for example, high amplitudes at frequencies in the range from 60 to 150 Hz. In this case, the predetermined disturbance frequency range is, for example, 60 to 150 Hz. Furthermore, in this case, the control frequency range of controlling the position of the first optical component is arranged in a preset manner in a frequency range which is at frequencies lower than 60 to 150 Hz. For example, the control frequency range of controlling the position of the first optical component is preset to a range of less than or equal to 40 Hz (e.g. 1 Hz to 40 Hz).

The first control frequency range and/or the disturbance frequency range is/are determined, for example, before the first start-up of the lithography apparatus and/or before producing controller equipment for controlling the position of the first optical component.

The predetermined disturbance frequency range is determined for example with the aid of acceleration sensors in three spatial directions (e.g., perpendicular to one another). For example, the acceleration sensors are mounted on the first optical component and/or a frame (e.g., carrier) of the first optical component in order to detect the disturbance excitation at the location of the first optical component.

According to a further embodiment of the first aspect, the first predetermined control frequency range is a frequency range in which the first deviation is less than 10%, less than 5%, less than 3%, less than 1%, less than 0.1% and/or less than 0.01% of the first target value.

According to a further embodiment of the first aspect, the position of the first optical component is controlled in a predetermined first control frequency range, the position of the second optical component is controlled in a predetermined second control frequency range, and the first and second control frequency ranges are different from one another.

As a result, the two items of controller equipment can be designed to be correspondingly adapted to position disturbances which correspondingly occur for an optical component which is temperature-controlled using a liquid and an optical component which is not temperature-controlled using a liquid.

The fact that the first and second control frequency ranges are different from one another means, for example, that the first and second control frequency ranges are of different widths and/or that the first control frequency range is smaller than the second control frequency range.

By way of example, the first and second control frequency ranges overlap (e.g., partially) and/or the first control frequency range is a subrange of the second control frequency range.

The second predetermined control frequency range is, for example, a frequency range in which the second deviation is less than 10%, less than 5%, less than 3%, less than 1%, less than 0.1% and/or less than 0.01% of the second target value.

According to a further embodiment of the first aspect:
the position of the first optical component and/or of the second optical component is controlled in each case with the aid of controller equipment which has at least one proportional controller element, at least one integral controller element and at least one derivative controller element, and/or
the predetermined first control frequency range is preset for controlling the position of the first optical component by increasing the number of integral controller elements of the controller equipment.

By way of example, the position of the first optical component is controlled with the aid of first controller equipment. Furthermore, the position of the second optical component is controlled, for example, with the aid of second controller equipment.

The respective controller equipment has, for example, a controller unit (e.g., a software unit) and a controller component (e.g., a hardware component). In addition, the respective controller component has, for example, the at least one proportional controller element, the at least one integral controller element and the at least one derivative controller element.

The first and/or second controller equipment has, for example, a PID controller (that is to say a controller having exactly one proportional controller element, exactly one integral controller element and exactly one derivative controller element).

Alternatively, in the first controller equipment, the number of integral controller elements of the controller equipment can be increased in comparison with the number of proportional controller elements and derivative controller elements. The first controller equipment has, for example, a PI3D controller (i.e., having exactly one proportional controller element, three integral controller elements and exactly one derivative controller element).

Increasing the number of integral controller elements of the first controller equipment for controlling the position of the first optical component makes it possible to shift the first control frequency range to lower frequencies. As a result, the first control frequency range for controlling the position of the first optical component which is temperature-controlled using a liquid can be shifted into a frequency range in which disturbance excitations are low and/or not present. Resonance transmissions can thus be avoided even better.

According to a further embodiment of the first aspect:
the first and second optical components are arranged successively in relation to a beam path of the lithography apparatus,
the first and second optical components are both arranged in an imaging beam path of the lithography apparatus,
the first and second optical components are both components of a projection system of the lithography apparatus, and/or
the first and second optical components are both configured to image a mask on a substrate arranged in an image plane of the lithography apparatus and/or of the projection system of the lithography apparatus.

The first and second optical components are thus arranged in such a way that they are part of the same optical system in which a beam path is forwarded between a plurality of optical elements. Consequently, beams that have already passed through the first optical component (for example have been reflected at it) or vice versa are incident on the second optical component.

The fact that the first and second optical components are arranged successively in relation to a beam path of the lithography apparatus comprises, for example, the case in which they are arranged in direct succession. When arranged in direct succession, no further optical elements (e.g., mirrors) are arranged between the first and second optical components in relation to the beam path.

However, the fact that the first and second optical components are arranged successively in relation to a beam path of the lithography apparatus may also comprise the case, for example, in which further optical elements (e.g., mirrors) are arranged between the first and second optical components in relation to the beam path.

According to a further embodiment of the first aspect, the method comprises a step of controlling a pressure of a liquid in a liquid line, which is configured to control the temperature of the first optical component using a liquid. Here, an actual pressure value of the pressure of the liquid is received, a further manipulated variable is determined on the basis of a pressure deviation of the actual pressure value from a target pressure value, and further actuator equipment of pressure-changing equipment is actuated on the basis of the determined further manipulated variable to change the pressure of the liquid in the liquid line.

As a result, pressure fluctuations of the liquid can be actively suppressed. In particular, a pressure fluctuation of the liquid can be compensated for before it is passed on to the first optical component to be temperature-controlled (for example to be cooled). A change in position of the first optical component caused by pressure fluctuations of the liquid can thus be reduced or avoided.

The target pressure value is zero, for example. However, the target pressure value can also have another preset value not equal to zero.

The pressure of the liquid in the liquid line is controlled in particular in such a way that the pressure deviation of the actual pressure value from the target pressure value is kept as small as possible.

For example, the pressure-changing equipment has an expansion chamber, which is fluidically connected to a liquid line, for receiving the liquid. In addition, the expansion chamber comprises means for changing a volume of the expansion chamber. In this way, a pressure of the liquid can be changed by changing the volume of the expansion chamber.

According to a further embodiment of the first aspect, the position of the first optical component is controlled in a predetermined first control frequency range, the pressure of the liquid in the liquid line is controlled in a predetermined further control frequency range, and the first and the further control frequency range are different from one another.

Consequently, the pressure is controlled in such a way that pressure fluctuations are compensated for at the frequencies at which the control of the position of the first optical component does not function well (that is to say control errors are large).

By way of example, the further predetermined control frequency range is a frequency range in which the pressure deviation is less than 10%, less than 5%, less than 3%, less than 1%, less than 0.1% and/or less than 0.01% of the target pressure value.

According to a second aspect, a computing device for compensating for liquid-transmitted acoustic disturbance excitations of an optical component of a lithography apparatus is proposed, said optical component being temperature-controlled using a liquid. The disturbance excitations of the optical component, as a first optical component, are compensated for with the aid of a second optical component of the lithography apparatus, said second optical component not being temperature-controlled using a liquid. The computing device comprises:
a receiving unit for receiving a first and second actual value of a position corresponding to the first and second optical components, and
a controller unit for controlling the position of the second optical component to an adapted target value of the position of the second optical component, said target value being based on an initial target value of the position of the second optical component and the first actual value of the position of the first optical component.

In embodiments, the controller unit for controlling the position of the second optical component is a second controller unit. Moreover, the computing device has a first controller unit for controlling a position of the first optical component.

In embodiments, the computing device comprises first and/or second actuating equipment for actuating first and/or second actuator equipment accordingly on the basis of the first and/or second determined manipulated variable.

According to a third aspect, a compensation system for compensating for liquid-transmitted acoustic disturbance excitations of an optical component of a lithography apparatus is proposed, said optical component being temperature-controlled using a liquid. The disturbance excitations of the optical component, as a first optical component, are compensated for with the aid of a second optical component of the lithography apparatus, said second optical component not being temperature-controlled using a liquid. The compensation system comprises:
the first optical component which is temperature-controlled using a liquid,
the second optical component which is not temperature-controlled using a liquid,
actuator equipment for setting a position of the second optical component, and
a computing device as described above for determining a manipulated variable on the basis of a deviation of the second actual value from the adapted target value and for actuating the actuator equipment to position the second optical component on the basis of the manipulated variable.

The manipulated variable according to the third aspect corresponds in particular to the second manipulated variable described above. Furthermore, the deviation according to the third aspect corresponds in particular to the second deviation described above. Furthermore, the actuator equipment according to the third aspect corresponds in particular to the second actuator equipment described above.

According to a fourth aspect, a lithography apparatus, in particular an EUV lithography apparatus, is proposed. The lithography apparatus has a computing device as described above or a compensation system as described above.

According to a fifth aspect, a method for producing controller equipment for controlling a position of an optical component of a lithography apparatus is proposed, said optical component being temperature-controlled using a liquid. The method comprises the steps of:
determining a disturbance frequency range of acoustic disturbance excitations of the optical component, and
configuring a controller component of the controller equipment in such a way that the position of the optical component is controlled in a predetermined control frequency range which is different from the predetermined disturbance frequency range.

The method serves in particular to produce the above-described first controller equipment for controlling the position of the above-described first optical component of the lithography apparatus, said optical component being temperature-controlled using a liquid. In this case, the predetermined control frequency range corresponds, for example, to the first predetermined control frequency range described above.

The configuration of the controller component of the controller equipment is, for example, configuration of a controller hardware component of the controller equipment.

The respective computing device, receiving unit, controller unit, and actuating equipment described above or below, and other units, equipment, and devices described herein, may be implemented in the form of hardware and/or software. In the case of an implementation in the form of hardware, the respective unit may be designed for example as a computer or as a microprocessor. In the case of an implementation in the form of software, the respective unit may be designed as a computer program product, as a function, as a routine, as an algorithm, as part of a program code or as an executable object. Furthermore, the corresponding unit can also be designed as part of a superordinate control system of the lithography apparatus.

“A” or “an” or “one” in the present case should not necessarily be understood as being restrictive to exactly one element. Rather, multiple elements, for example two, three or more, may also be provided. Any other numeral used here should also not be understood as a restriction to exactly the stated number of elements. Rather, unless indicated to the contrary, numerical upward and downward deviations are possible.

The embodiments and features described for the method according to the first aspect apply, mutatis mutandis, to the second to fifth aspects, and vice versa.

Further possible implementations of the invention also comprise combinations, not explicitly mentioned, of features or embodiments described above or below with regard to the exemplary embodiments. A person skilled in the art will also add individual aspects as improvements or additions to the respective basic form of the invention.

### BRIEF DESCRIPTION OF DRAWINGS

Further advantageous configurations and aspects of the invention are the subject matter of the dependent claims and also of the exemplary embodiments of the invention that are described below. The invention will be explained in more detail below on the basis of preferred embodiments with reference to the appended figures.

FIG. 1 shows a schematic meridional section of a projection exposure apparatus for EUV projection lithography;

FIG. 2 shows a projection system and a compensation system of the projection exposure apparatus from FIG. 1 according to a respective embodiment, wherein the compensation system is configured to compensate for liquid-transmitted acoustic disturbance excitations of an optical component of the projection system, said optical component being temperature-controlled using a liquid;

FIG. 3 shows first controller equipment of the compensation system from FIG. 2 according to one embodiment;

FIG. 4 shows second controller equipment of the compensation system from FIG. 2 according to one embodiment;

FIG. 5 shows a flowchart of a method for compensating for liquid-transmitted acoustic disturbance excitations of an optical component of the projection system from FIG. 2, said optical component being temperature-controlled using a liquid, according to one embodiment;

FIG. 6 shows a block diagram of a first and second control loop of the compensation system from FIG. 2 according to one embodiment;

FIG. 7 shows a second control loop of the compensation system from FIG. 2 according to a further embodiment;

FIG. 8 illustrates a frequency range of an acoustic disturbance excitation and a plurality of controller frequency ranges of the compensation system from FIG. 2 according to one embodiment,

FIG. 9 shows a controller component of the first or second controller equipment from FIG. 3 or 4 according to one embodiment;

FIG. 10 shows a controller component of the first controller equipment from FIG. 3 according to a further embodiment;

FIG. 11 shows a third control loop of the compensation system from FIG. 2 according to one embodiment; and

FIG. 12 shows a flowchart of a method for producing controller equipment of the compensation system from FIG. 2 for controlling a position of an optical component of the projection system from FIG. 2, said optical component being temperature-controlled using a liquid.

### DETAILED DESCRIPTION

In the figures, identical or functionally identical elements have been provided with the same reference signs, unless indicated otherwise. It should also be noted that the illustrations in the figures are not necessarily true to scale.

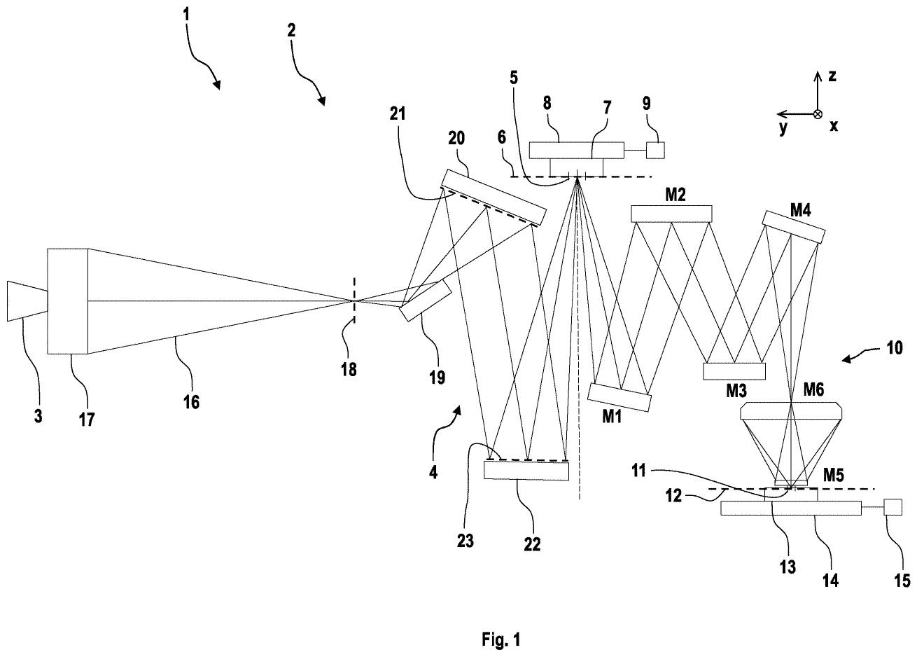

FIG. 1 shows one embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, in particular in a scanning direction.

FIG. 1 depicts, by way of elucidation, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14.

The wafer holder 14 is displaceable by way of a wafer displacement drive 15, in particular in the y-direction y. The displacement, firstly, of the reticle 7 by way of the reticle displacement drive 9 and, secondly, of the wafer 13 by way of the wafer displacement drive 15 may be implemented so as to be synchronized with one another.

The light source 3 is an EUV radiation source. The light source 3 emits in particular EUV radiation 16, which is also referred to below as used radiation, illumination radiation or illumination light. The used radiation 16 has in particular a wavelength in the range between 5 nm and 30 nm. The light source 3 can be a plasma source, for example an LPP (short for: laser produced plasma) source or a DPP (short for: gas-discharge produced plasma) source. It can also be a synchrotron-based radiation source. The light source 3 can be a free electron laser (FEL).

The illumination radiation 16 emanating from the light source 3 is focused by a collector 17. The collector 17 may be a collector having one or more ellipsoidal and/or hyperboloidal reflection surfaces. The at least one reflection surface of the collector 17 can be impinged on by the illumination radiation 16 with grazing incidence (GI), i.e. with angles of incidence greater than 45°, or with normal incidence (NI), i.e. with angles of incidence less than 45°. The collector 17 can be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optical unit 4.

The illumination optical unit 4 comprises a deflection mirror 19 and, disposed downstream thereof in the beam path, a first facet mirror 20. The deflection mirror 19 may be a planar deflection mirror or alternatively a mirror with a beam-influencing effect that goes beyond the pure deflection effect. Alternatively or additionally, the deflection mirror 19 can be designed as a spectral filter that separates a used light wavelength of the illumination radiation 16 from extraneous light having a wavelength that deviates therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 may take the form of macroscopic facets, in particular the form of rectangular facets or the form of facets with an arcuate or partly circular peripheral contour. The first facets 21 may take the form of planar facets or alternatively convexly or concavely curved facets.

As known from DE 10 2008 009 600 A1 for example, the first facets 21 themselves may also be composed in each case of a multiplicity of individual mirrors, in particular a multiplicity of micromirrors. The first facet mirror 20 may in particular take the form of a microelectromechanical system (MEMS system). For details, reference is made to DE 10 2008 009 600 A1.

The illumination radiation 16 travels horizontally, i.e. in the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 may also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which can for example have a round, rectangular or else hexagonal boundary, or may alternatively be facets composed of micromirrors. In this regard, reference is likewise made to DE 10 2008 009 600 A1.

The second facets 23 may have planar or alternatively convexly or concavely curved reflection surfaces.

The illumination optical unit 4 thus forms a doubly faceted system. This fundamental principle is also referred to as a fly's eye integrator.

It may be advantageous to not arrange the second facet mirror 22 exactly in a plane that is optically conjugate to a pupil plane of the projection optical unit 10. In particular, the second facet mirror 22 can be arranged so as to be tilted in relation to a pupil plane of the projection optical unit 10, as described for example in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 may be arranged in the beam path between the second facet mirror 22 and the object field 5. The transfer optical unit may have exactly one mirror or else, alternatively, two or more mirrors arranged in succession in the beam path of the illumination optical unit 4. The transfer optical unit may in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20 and the second facet mirror 22.

In a further embodiment of the illumination optical unit 4, the deflection mirror 19 can also be omitted, and so the illumination optical unit 4 may have exactly two mirrors downstream of the collector 17 in that case, specifically the first facet mirror 20 and the second facet mirror 22.

The imaging of the first facets 21 into the object plane 6 by use of the second facets 23 or using the second facets 23 and a transfer optical unit is generally only approximate imaging.

The projection optical unit 10 comprises a plurality of mirrors Mi numbered consecutively in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and can be for example 0.7 or 0.75.

Reflection surfaces of the mirrors Mi may take the form of free-form surfaces without an axis of rotational symmetry. Alternatively, the reflection surfaces of the mirrors Mi may take the form of aspherical surfaces with exactly one axis of rotational symmetry of the reflection surface shape. Just like the mirrors of the illumination optical unit 4, the mirrors Mi may have highly reflective coatings for the illumination radiation 16. These coatings may be designed as multilayer coatings, in particular with alternating layers of molybdenum and silicon.

The projection optical unit 10 has a large object-image shift in the y-direction y between a y-coordinate of a center of the object field 5 and a y-coordinate of the center of the image field 11. This object-image shift in the y-direction y can be of approximately the same magnitude as a z-distance between the object plane 6 and the image plane 12.

The projection optical unit 10 may in particular be of anamorphic design. In particular, it has different imaging scales βx, βy in the x-direction x and y-direction y. The two imaging scales βx, βy of the projection optical unit 10 are preferably (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x-direction x and y-direction y are known from US 2018/0074303 A1.

In each case, one of the second facets 23 is assigned to exactly one of the first facets 21 in order to form a respective illumination channel for illuminating the object field 5. In particular, this may result in illumination according to the Köhler principle. The far field is broken down into a multiplicity of object fields 5 with the aid of the first facets 21. The first facets 21 generate a plurality of images of the intermediate focus on the second facets 23 respectively assigned to them.

The first facets 21 are each imaged onto the reticle 7 by an assigned second facet 23 with images overlaid over one another for the purpose of illuminating the object field 5. The illumination of the object field 5 is in particular as homogeneous as possible. It preferably has a uniformity error of less than 2%. Field uniformity can be achieved by overlaying different illumination channels.

An arrangement of the second facets 23 may be used to geometrically define the illumination of the entrance pupil of the projection optical unit 10. The intensity distribution in the entrance pupil of the projection optical unit 10 may be set by selecting the illumination channels, in particular the subset of the second facets 23 that guide light. This intensity distribution is also referred to as illumination setting or illumination pupil filling.

A likewise preferred pupil uniformity in the region of portions of an illumination pupil of the illumination optical unit 4 that are illuminated in a defined manner may be achieved by a redistribution of the illumination channels.

There follows a description of further aspects and details of the illumination of the object field 5 and in particular of the entrance pupil of the projection optical unit 10.

The projection optical unit 10 may have in particular a homocentric entrance pupil. This may be accessible. It may also be inaccessible.

The entrance pupil of the projection optical unit 10 regularly cannot be exactly illuminated using the second facet mirror 22. In the case of imaging by the projection optical unit 10 which telecentrically images the center of the second facet mirror 22 onto the wafer 13, the aperture rays often do not intersect at a single point. However, it is possible to find an area in which the spacing of the aperture rays, which is determined in pairs, becomes minimal. This area is the entrance pupil or an area conjugate thereto in position space. In particular, this area exhibits a finite curvature.

It may be the case that the projection optical unit 10 has different poses of the entrance pupil for the tangential beam path and for the sagittal beam path. In this case, an imaging element, in particular an optical structural element of the transfer optical unit, should be provided between the second facet mirror 22 and the reticle 7. This optical element may be used to take into account the different poses of the tangential entrance pupil and the sagittal entrance pupil.

In the arrangement of the components of the illumination optical unit 4 illustrated in FIG. 1, the second facet mirror 22 is arranged in an area conjugate to the entrance pupil of the projection optical unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

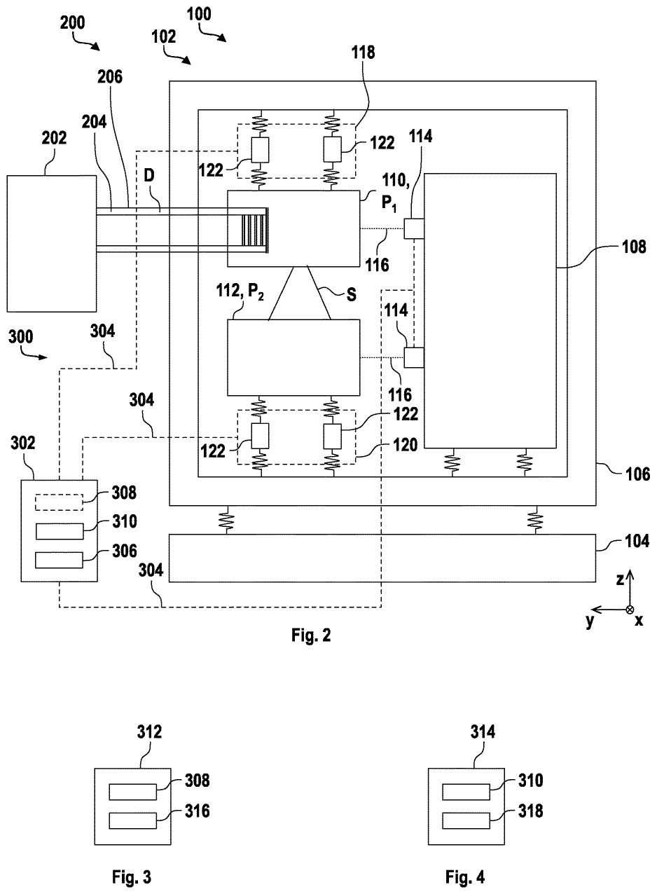

FIG. 2 shows an example of a projection system 100 having a projection optical unit 102 of the lithography apparatus 1 from FIG. 1 according to one embodiment.

FIG. 2 schematically illustrates a plurality of exemplary frame structures (carrier structures) 104, 106, 108 of the projection system 100. Moreover, FIG. 1 illustrates a first optical component 110 and a second optical component 112 of the projection system 100. By way of example, the first and second optical components 110, 112 are each mirrors. By way of example, the mirrors 110, 112 are two of the mirrors M1 to M6 from FIG. 1. Hereinafter, the first and second optical components 110, 112 are described as first and second mirrors 110, 112, without restricting them thereto. Although not shown in FIG. 2, the projection system 100 can also have further mirrors and/or optical components in addition to the first and second mirrors 110, 112.

The frame structure 108 is, for example, a sensor frame of the projection system 100. Arranged on the sensor frame 108 is, for example, sensor equipment 114 which can be used to measure a current position P₁, P₂ (actual values y₁(t) and y₂(t) corresponding to the position P₁, P₂, see FIG. 6) of the first and second mirrors 110, 112 relative to the sensor frame 108. The sensor equipment 114 is only schematically indicated in FIG. 2. The sensor equipment 114 comprises one or more sensors fastened to the sensor frame 108, such as interferometers. By way of example, a current position y₁(t) of the first mirror 110 and a current position y₂(t) of the second mirror 112 are captured with the aid of laser beams 116. For example, the current positions y₁(t), y₂(t) of the first and second mirrors 110, 112 are captured with respect to six degrees of freedom. The six degrees of freedom comprise in particular three degrees of translation freedom in the x-direction, y-direction and z-direction in FIG. 2 and three degrees of rotation freedom about the x-direction, y-direction and z-direction.

The reference sign 106 in FIG. 2 denotes, for example, a force frame of the mirrors 110, 112. The mirrors 110, 112 are fastened so as to be movable on the force frame 106, in particular using actuator equipment 118, 120 in each case. Each of the first and second items of actuator equipment 118, 120 comprises one or more actuators 122 for positioning the corresponding first and second mirrors 110, 112. By way of example, the mirrors 110, 112 are each displaceable in the six degrees of freedom by use of the actuators 122. The mirrors 110, 112 are also fastened to the force frame 106 in a vibration-decoupled manner, for example.

In addition, the sensor frame 108 is also mounted in a vibration-decoupled manner, for example, with respect to the force frame 106. Furthermore, the force frame 106 is mounted in a vibration-decoupled manner-for example with respect to a frame structure 104 and/or a floor.

FIG. 2 also shows a temperature control device 200 for controlling the temperature of the first mirror 110. The temperature control device 200 is described below by way of example as a cooling device 200, wherein the temperature control device 200 can also serve to heat the mirror 110 in other embodiments. The first mirror 110 is temperature-controlled using a liquid (e.g., liquid-cooled) with the aid of the temperature control device 200. However, the second mirror 112 is not temperature-controlled using a liquid (e.g., liquid-cooled). This fact is used below for advantageous compensation for liquid-transmitted acoustic disturbance excitations of the first mirror 110 which is temperature-controlled using a liquid.

Although not shown in FIG. 2, the temperature control device 200 can also be used, in addition to the first mirror 110, to control the temperature of other components of the projection system 100—with the exception of the second mirror 112. For example, the temperature control device 200 can also be configured to control the temperature of the sensor frame 108 or other mirrors (not shown).

The cooling device 200 (as an example of a temperature control device 200) comprises a cooling unit 202 for cooling a cooling liquid 204. The cooling device 200 also comprises one or more liquid lines 206 for transporting the cooling liquid 204 from the cooling unit 202 to the component 110 to be cooled and back to the cooling unit 202. The cooling device 200 moreover comprises one or more pumps (not shown) for producing a required flow rate of the cooling liquid 204. The cooling device 200 furthermore comprises one or more valves (not shown) for controlling the cooling flow.

FIG. 2 additionally shows a compensation system 300 for compensating for liquid-transmitted acoustic disturbance excitations of the first mirror 110 which is temperature-controlled using a liquid. In this case, the disturbance excitations of the first mirror 110 are compensated for with the aid of the second mirror 112 which is not temperature-controlled using a liquid. The compensation system 300 may be part of the projection system 100.

The compensation system 300 comprises the liquid-cooled first mirror 110 and the non-liquid-cooled second mirror 112. The compensation system 300 additionally comprises the second actuator equipment 120 for setting the position P2 of the second mirror 112. The compensation system 300 can optionally also have first actuator equipment 118 for setting the position P₁ of the first mirror 110.

In addition, a computing device 302 is provided in the compensation system 300. The computing device 302 is connected to the sensor equipment 114 and the second actuator equipment 120 for (wireless or wired) data transmission 304. Optionally, the computing device 302 can also be connected to the first actuator equipment 118, for example, for data transmission 304.

The computing device 302 has a receiving unit 306 for receiving the first actual value y₁(t) of the position P₁ of the first mirror 110 and the second actual value y₂(t) of the position P₂ of the second mirror.

The computing device 302 optionally has a controller unit 308 (first controller unit 308) for controlling the position P₁ of the first mirror 110. The computing device 302 additionally has a second controller unit 310 for controlling the position P₂ of the second mirror 112.

As illustrated in FIGS. 3 and 4, the compensation system 300 can have first controller equipment 312 for controlling the position P₁ of the first mirror 110 and/or second controller equipment 314 for controlling the position P₂ of the second mirror 112. The first controller equipment 312 comprises the controller unit 308 which is realized, for example, as a software component. Furthermore, the first controller equipment 312 comprises a controller component 316 which is realized, for example, as a hardware component. Similarly, the second controller equipment 314 comprises the controller unit 310 which is realized, for example, as a software component, and a controller component 318 which is realized, for example, as a hardware component.

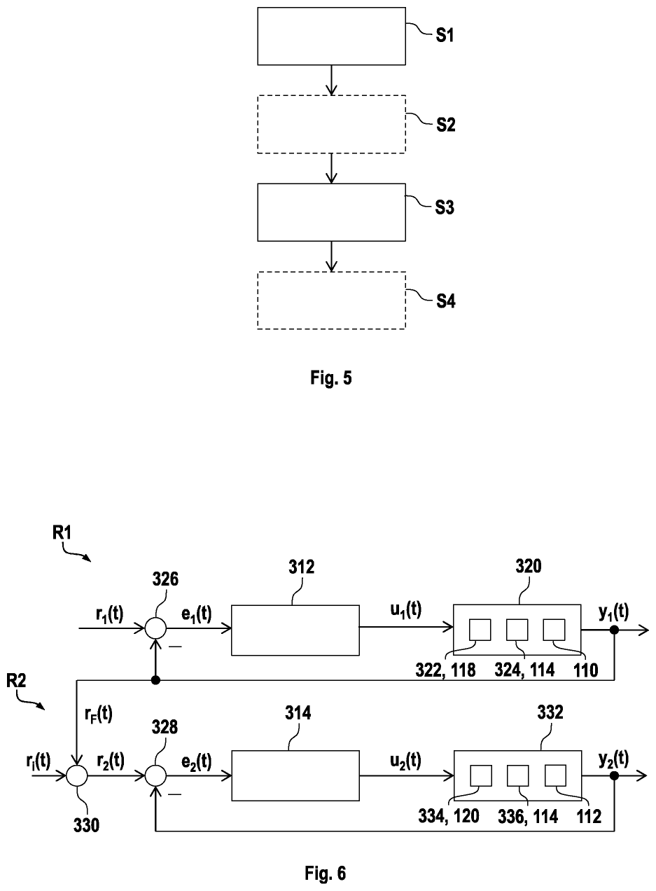

A method for compensating for liquid-transmitted acoustic disturbance excitations of an optical component (e.g. of the first mirror 110) of a lithography apparatus 1, said optical component being temperature-controlled using a liquid, is described below with reference to FIG. 5. In this case, the disturbance excitations of the first optical component 110, e.g. of the first mirror 110, are compensated for with the aid of a second optical component 112, e.g. of the second mirror 112, of the lithography apparatus 1, said second optical component not being temperature-controlled using a liquid.

In a first step S1 of the method, a first actual value y₁(t) of the position P₁ of the first mirror 110 is received. Furthermore, a second actual value y₂(t) of the position P₂ of the second mirror 112 is received. The actual values y₁(t), y₂(t) are captured, for example, by the sensor equipment 114 and transmitted by data transmission 304 to the receiving unit 306 of the computing device 302.

In an optional second step S2 of the method, a position P₁ of the first mirror 110 is controlled to a first target value n(t) for the position P₁ of the first mirror 110.

FIG. 6 shows a block diagram illustrating control of the position P₁ of the first mirror 110 (control loop R1). The control of the position P₁ of the first mirror 110 is based on feedback control. The feedback control is implemented by the controller equipment 312 and a controlled system 320. The controlled system 320 comprises an actuator system 322 for manipulating the position P₁ of the first mirror 110. The actuator system 322 is realized in particular by the first actuator equipment 118 (FIG. 2). The controlled system 320 furthermore comprises a sensor system 324 for measuring the current position y₁(t) of the first mirror 110. The sensor system 324 is realized in particular by the sensor equipment 114 (FIG. 2). Furthermore, the controlled system 320 comprises the first mirror 110.

The controller equipment 312, together with the controlled system 320, forms the feedback control in the control loop R1 and ensures that a first deviation e₁(t) of the first actual position y₁(t) from a first target position r₁(t) of the first mirror 110 is held at a value that is as small as possible, ideally zero. The target position r₁(t) may be a static value (r₁(t)=const.) or can also be a function which depends on the time t (r₁(t)≠const.). In particular, the target position r₁(t) of the first mirror 110 can also follow any (constant or changeable) trajectory in (e.g. three-dimensional) space.

The received first actual value y₁(t) is transmitted, that is to say returned or fed back, from the receiving unit 306 to the first controller equipment 312, in particular the first controller unit 308. For example, the first actual value y₁(t) is fed back negatively to the controller equipment 312 (minus sign in FIG. 6).

In step S2, the first deviation e₁(t) of the first actual value y₁(t) from the first target value r₁(t) is also determined. The first deviation e₁(t) is determined, for example, by the controller equipment 312 or by an upstream summation unit 326. For example, the first actual value y₁(t) is subtracted from the first target value r₁(t). To determine the first deviation e₁(t), the first target value r₁(t) is stored, in particular saved, in the first controller equipment 312 or in the upstream summation unit 326.

Furthermore, in step S2, a first manipulated variable u₁(t) is determined on the basis of the first deviation e₁(t).

Then, the first actuator equipment 118 is actuated to position the first mirror 110 on the basis of the determined first manipulated variable u₂(t).

Since the first mirror 110 is temperature-controlled using a liquid and is thus subject to acoustic disturbance excitations, a control error e₁(t) when controlling the position P₁ of the first mirror 110 can be relatively large. The control error when controlling the position P₁ of the first mirror 110 can advantageously be at least partially compensated for here when controlling the position P₂ of the second mirror 112 in step S3.

In a third step S3 of the method, the position P₂ of the second mirror 112 is controlled.

The block diagram in FIG. 6 illustrates, in the lower region, a control loop R2 for controlling the position P₂ of the second mirror 112 in feedback control.

When controlling the position P₂ of the second mirror 112 as well—in a similar manner to that when controlling the position P₁ of the first mirror 110—a second actual value y₂(t) is fed back to the second controller equipment 314 or a second summation unit 328. First, a second deviation e₂(t) of the second actual value y₂(t) from a target value r₂(t) is determined and a second manipulated variable u₂(t) is calculated on the basis of the determined second deviation e₂(t). Then, the second actuator equipment 120 is actuated to position the second mirror 112 on the basis of the second manipulated variable u₂(t).

In a similar manner to that in the first control loop R1, the feedback control of the second control loop R2 is implemented by the second controller equipment 314 and a second controlled system 332. The controlled system 332 comprises an actuator system 334 for manipulating the position P₂ of the second mirror 112, which is realized in particular by the second actuator equipment 120 (FIG. 2). The second controlled system 332 furthermore comprises a sensor system 336 for measuring the current position y₂(t) of the second mirror 112. The sensor system 336 is realized in particular by the sensor equipment 114 (FIG. 2). Furthermore, the controlled system 332 comprises the second mirror 112.

The special feature when controlling the position P₂ of the second mirror 112 (control loop R2) is that an adapted target value r₂(t) is used to determine the second deviation e₂(t), said target value being based on an initial target value rᵢ(t) of the position (P₂) of the second mirror 112 and the first actual value y₁(t) of the position P₁ of the first mirror 112. In other words, the position P₂ of the second mirror 112 is controlled to a target position r₂(t) that includes the actual position y₁(t) of the first mirror 110.

In particular, in the embodiment of FIG. 6, the first actual value y₁(t) of the position P₁ of the first mirror 112 in the first control loop R1 is fed back to the first controller equipment 312 or the summation unit 326. In addition, the first actual value y₁(t) of the position P₁ of the first mirror 112 is transferred to the second control loop R2. By way of example, the first actual value y₁(t) is transferred as a feed-through target value r_{F}(t) of the first mirror 110 to the second control loop R2, for example to a further summation unit 330 of the second control loop R2.

The adapted target value r₂(t) is determined, for example, by summing the initial target value rᵢ(t) and the first actual value y₁(t) or the feed-through target value r_{F}(t):

r₂(t)=r₁(t)+y₁(t)=rᵢ(t)+r_{F}(t)

A position error of the first mirror 110, which is temperature-controlled using a liquid, can thus be forwarded to the control loop R2 of the second mirror 112, which is not temperature-controlled using a liquid, on account of liquid-transmitted acoustic disturbance excitations. The control loop R2 of the second mirror 112, which is not temperature-controlled using a liquid, can consequently at least partially also compensate for a position error of the first mirror 110, which is temperature-controlled using a liquid, by controlling the position P₂ of the second mirror 112.

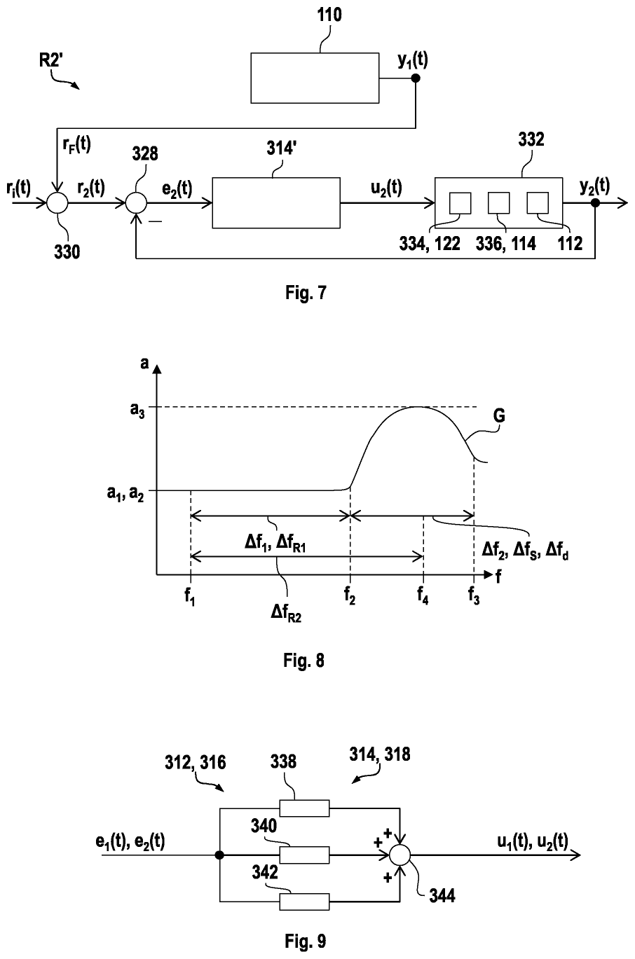

FIG. 7 illustrates a block diagram in relation to a further embodiment of the method for compensating for liquid-transmitted acoustic disturbance excitations of the first mirror 110 which is temperature-controlled using a liquid. In this embodiment, the position P₁ of the first mirror 110 is not controlled. The position P₂ of the second mirror 112 is controlled with the aid of a second control loop R2′ and second controller equipment 314′. The second control loop R2′ according to the embodiment in FIG. 7 differs from the second control loop R2 according to the embodiment in FIG. 6 only in that the first actual value y₁(t) transmitted to the second control loop R2 is an actual value y₁(t) of an uncontrolled position P₁ of the first mirror 110. That is to say, in the embodiment of FIG. 6, the second control loop R2 is configured to compensate for only one remaining control error of the first mirror 110. By contrast, in the embodiment of FIG. 7, the second control loop R2′ is configured to control the position P₁ of the first mirror 110 completely on its own.

Since the first mirror 110 is liquid-cooled and is thus impaired by acoustic disturbance excitations transmitted via the cooling liquid, the resonances of a disturbance excitation and a transfer function of the first controller equipment 312 can be superimposed. In order to avoid or reduce this, a control frequency range Δf₁ of the first control loop R1 (for example when producing the first controller equipment 312) can be suitably preset.

FIG. 8 schematically illustrates a frequency range Δfₛ of a disturbance excitation. In particular, FIG. 8 shows a diagram which indicates an acceleration a (e.g., in one of the three spatial directions x, y, z) of the first mirror 110 on the basis of a frequency f. A graph G shows a function of the acceleration a of the first mirror 110 on the basis of the frequency f as a result of a disturbance excitation. As can be seen in FIG. 8, the acceleration a in a first frequency range Δf₁ from a frequency f₁ to a frequency f₂ is very low and/or zero (a₁, a₂). Furthermore, an acceleration a with large amplitudes occurs in a second frequency range Δf₂ from a frequency f₂ to a frequency f₃. The acceleration a of the first mirror 110 on account of disturbance excitations can be determined (although not shown in FIG. 8) in all three spatial directions x, y, z. The acceleration a of the first mirror 110 on account of disturbance excitations can be determined, for example, by use of acceleration sensors (not shown) mounted on the first mirror 110 or a mirror body of the first mirror 110. A disturbance frequency range Δf_{S} of the acoustic disturbance excitations of the first mirror 110 can be determined with the aid of these sensor-captured values.

In order to avoid resonances during control in the control loop R1 and position errors of the first mirror 110 that are caused thereby, the position P₁ of the first mirror 110 can be controlled in a predetermined control frequency range Δf_{R1} which is different from the disturbance frequency range Δf_{S}. Merely by way of example, the range Δf₁ in FIG. 8 can be determined as a suitable control frequency range Δf_{R1}. By way of example, the first predetermined control frequency range Δf_{R1} can be determined as a frequency range for which the control deviation e₁(t) of the control loop R1 is less than 10%, less than 5%, less than 3%, less than 1%, less than 0.1% and/or less than 0.01% of the first target value r₁(t).

Moreover, the position P₂ of the second mirror 112 can be controlled by use of the second control loop R2 in a predetermined second control frequency range Δf_{R2} which is different from the first control frequency range Δf_{R1}. Since the second mirror 112 is not liquid-cooled, it is not subject to any acoustic disturbance excitations, unlike the first mirror 110. Therefore, it is not necessary to avoid the disturbance frequency range Δf_{S} in the second control loop R2. The second control frequency range Δf_{R2} can thus be preset to be broader. In the example of FIG. 8, the second control frequency range Δf_{R2} comprises frequencies of f₁ to f₄, where f₄ is greater than the upper frequency limit f₂ of the first control frequency range Δf_{R1}.

FIG. 9 shows an embodiment of the controller equipment 312, 314, in particular of the controller component 316, 318 of the controller equipment 312, 314 (FIGS. 3 and 4). The corresponding controller component 316, 318 has at least one proportional controller element 338, at least one integral controller element 340 and at least one derivative controller element 342. The contributions to the manipulated variable u₁(t) that are determined by the controller elements 338, 340, 342 are combined at a further summation unit 344.

In the example of FIG. 9, the controller component 316, 318 has exactly one proportional controller element 338, exactly one integral controller element 340 and exactly one derivative controller element 342 (so-called PID controller).

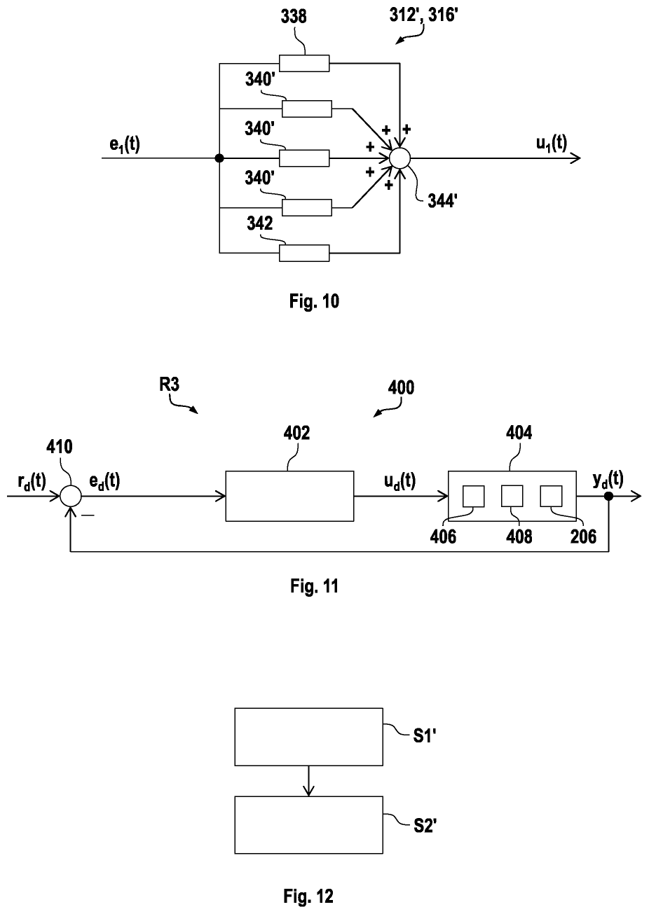

In a further example shown in FIG. 10, a controller component 316′ of the first controller equipment 312′ has one proportional controller element 338, three integral controller elements 340′ and one derivative controller element 342 (so-called PI3D controller). Increasing the number of integral controller elements 342 of the controller equipment 312′ for controlling the position P₁ of the first mirror 110 makes it possible to shift the first control frequency range Δf_{R1} to lower frequencies (FIG. 8). As a result, the first control frequency range Δf_{R1} for controlling the position P₁ of the first mirror 110 which is temperature-controlled using a liquid can be shifted into a frequency range in which disturbance excitations are low. Resonance transmissions can thus be avoided to an even greater extent.

In an optional fourth step S4 of the method, a pressure D (FIG. 2) of the temperature control liquid 204 in the liquid line 206, which is configured to control the temperature of the first mirror 110 using a liquid, is actively controlled.

FIG. 11 illustrates a third control loop R3 for controlling the pressure D of the temperature control liquid 204 (for example cooling liquid 204). A pressure control device 400 comprises third controller equipment 402 and a third controlled system 404. The controlled system 404 comprises a sensor system 406 for capturing an actual value y_{d}(t) of the pressure D of the liquid 204, an actuator system 408 for changing the pressure D of the liquid 204 (pressure-changing equipment 410) and the liquid line 206.

During feedback control, a captured actual value y_{d}(t) of the pressure D of the liquid 204 is fed back to the third controller equipment 402 or a summation unit 412. A pressure deviation e_{d}(t) of the actual pressure value y_{d}(t) from a target pressure value r_{d}(t) is determined. The target pressure value r_{d}(t) is, for example, zero. The third controller equipment 402 then determines a further manipulated variable u_{d}(t) on the basis of the pressure deviation e_{d}(t). On the basis of the determined further manipulated variable dᵤ(t), further actuator equipment 408 of pressure-changing equipment 410 (for example an expansion chamber, not shown, which is fluidically connected to the liquid line 206) is then actuated to change the pressure D of the liquid 204 in the liquid line 206.

As a result of the active pressure control, pressure fluctuations of the liquid 204 can be actively suppressed. In particular, a pressure fluctuation of the liquid 204 can be compensated for before it is passed on to the first mirror 110 to be cooled. A change in position of the first mirror 110 caused by pressure fluctuations of the liquid 204 can thus be reduced or avoided to an even greater extent.

Optionally, the pressure D of the liquid 204 in the liquid line 206 can be controlled in a predetermined further control frequency range Δf_{d} (FIG. 8). By way of example, the predetermined further control frequency range Δf_{d} is selected such that it is different from the first control frequency range Δf_{R1} in which the position of the first mirror 110 is controlled. As shown in FIG. 8, the further control frequency range Δf_{d} and the first control frequency range Δf_{R1} do not overlap one another, for example. Consequently, the pressure is controlled in such a way that pressure fluctuations are compensated for at the frequencies at which the control of the position P₁ of the first mirror 110 has large control errors.

A method for producing controller equipment 312, 312′ (FIGS. 3, 9 and 10) for controlling a position P₁ of an optical component 110 (first optical component 110, FIG. 2) of a lithography apparatus 1 (FIG. 1), said optical component being temperature-controlled using a liquid, is described below with reference to FIG. 12.

In a first step S1′ of the method, a disturbance frequency range Δfₛ (FIG. 8) of acoustic disturbance excitations of the optical component 110 is determined.

The disturbance frequency range Δfₛ of the acoustic disturbance excitations of the optical component 110 is, in particular, a disturbance frequency range Δfₛ of the acoustic disturbance excitations of the optical component 110 during operation of the lithography apparatus 1. During operation of the lithography apparatus 1, the optical component is irradiated in particular with operating light 6, e.g. EUV light, and/or a substrate holder (wafer holder 14 in FIG. 1) and/or a mask holder (reticle holder 8 in FIG. 1) is/are moved.

In step S1′, the disturbance frequency range Δfₛ of acoustic disturbance excitations of the optical component 110 is determined for example by prediction (e.g., a model calculation) and/or by capture (e.g., by use of acceleration sensors).

In a second step S2′ of the method, a controller component 316 of the controller equipment 312, 312′ is configured (e.g., produced and/or set) in such a way that the position P₁ of the optical component 110 is controlled in a predetermined control frequency range Δf_{R1} which is different from the predetermined disturbance frequency range Δfₛ. By way of example, the controller component 316 is configured in such a way that the predetermined control frequency range Δf_{R1} and the predetermined disturbance frequency range Δfₛ do not overlap one another.

Although the present invention has been described on the basis of exemplary embodiments, it is modifiable in a variety of ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Projection system
102 Projection optical unit
104 Frame structure
106 Frame structure
108 Frame structure
110 Optical component
112 Optical component
114 Sensor equipment
116 Laser beam
118 Actuator equipment
120 Actuator equipment
122 Actuator
200 Temperature control device
202 Temperature control unit
204 Liquid
206 Liquid line
300 Compensation system
302 Computing device
304 Data transmission
306 Receiving unit
308 Controller unit
310 Controller unit
312, 312′ Controller equipment
314, 314′ Controller equipment
316, 316′ Controller component
318 Controller component
320 Controlled system
322 Actuator system
324 Sensor system
326 Summation unit
328 Summation unit
330 Summation unit
332 Controlled system
334 Actuator system
336 Sensor system
338 Controller element
340, 340′ Controller element
342 Controller element
344, 344′ Summation unit
400 Pressure control device
402 Controller equipment
404 Controlled system
406 Sensor system
408 Actuator equipment (actuator system)
410 Pressure-changing equipment
412 Summation unit
a Acceleration
a₁, a₂, a₃ Acceleration
D Pressure
Δf₁, Δf₂ Frequency range
Δf_{R1}, Δf_{R2} Frequency range
Δfₛ, Δf_{d} Frequency range
e₁, e₂, e_{d} Deviation
f Frequency
f₁, f₂, f₃, f₄ Frequency
G Graph
M1-M6 Mirror
P₁, P₂ Position
r₁, r₂ Target value
Tirᵢ, r_{F}, r_{d} Target value
R1-R3, R2′ Control loop
S Beam path
S1-S4 Method steps
S1′-S2′ Method steps
t Time
u₁, u₂, u_{d} Manipulated value
x, y, z Direction
y₁, y₂, y_{d} Actual value

What is claimed is:

1. A method for compensating for liquid-transmitted acoustic disturbance excitations of an optical component of a lithography apparatus, said optical component being temperature-controlled using a liquid, wherein the disturbance excitations of the optical component, as a first optical component, are compensated for with the aid of a second optical component of the lithography apparatus, said second optical component not being temperature-controlled using a liquid, comprising the steps of:
a) receiving a first and second actual value of a position corresponding to the first and second optical components, and
b) controlling the position of the second optical component to an adapted target value of the position of the second optical component, said target value being based on an initial target value of the position of the second optical component and the first actual value of the position of the first optical component.

2. The method as claimed in claim 1, comprising
controlling the position of the first optical component to a first target value of the position of the first optical component on the basis of the first actual value.

3. The method as claimed in claim 2, wherein controlling the position of the first optical component comprises:
determining a first manipulated variable on the basis of a first deviation of the first actual value from the first target value, and
actuating first actuator equipment to position the first optical component on the basis of the first manipulated variable.

4. The method as claimed in claim 1, wherein controlling the position of the second optical component comprises:
determining a second manipulated variable on the basis of a second deviation of the second actual value from the adapted target value, and
actuating second actuator equipment to position the second optical component on the basis of the second manipulated variable.

5. The method as claimed in claim 2, wherein the position of the first optical component is controlled in a first predetermined control frequency range which is different from a predetermined disturbance frequency range of the acoustic disturbance excitations of the first optical component.

6. The method as claimed in claim 5, wherein the first predetermined control frequency range is a frequency range in which the first deviation is less than 10%, less than 5%, less than 3%, less than 1%, less than 0.1% and/or less than 0.01% of the first target value.

7. The method as claimed in claim 2, wherein
the position of the first optical component is controlled in a predetermined first control frequency range,
the position of the second optical component is controlled in a predetermined second control frequency range, and
the first and second control frequency ranges are different from one another.

8. The method as claimed in claim 2, wherein
the position of the first optical component and/or of the second optical component is controlled in each case with the aid of controller equipment which has at least one proportional controller element, at least one integral controller element and at least one derivative controller element, and/or
the predetermined first control frequency range is preset for controlling the position of the first optical component by increasing the number of integral controller elements of the controller equipment.

9. The method as claimed in claim 1, wherein
the first and second optical components are arranged successively in relation to a beam path of the lithography apparatus,
the first and second optical components are both arranged in an imaging beam path of the lithography apparatus,
the first and second optical components are both components of a projection system of the lithography apparatus, and/or
the first and second optical components are both configured to image a mask on a substrate arranged in an image plane of the lithography apparatus and/or of the projection system of the lithography apparatus.

10. The method as claimed in claim 1, comprising
controlling a pressure of a liquid in a liquid line, which is configured to control the temperature of the first optical component using a liquid, wherein:
an actual pressure value of the pressure of the liquid is received,
a further manipulated variable is determined on the basis of a pressure deviation of the actual pressure value from a target pressure value, and
further actuator equipment of pressure-changing equipment is actuated on the basis of the determined further manipulated variable to change the pressure of the liquid in the liquid line.

11. The method as claimed in claim 10, wherein
the position of the first optical component is controlled in a predetermined first control frequency range,
the pressure of the liquid in the liquid line is controlled in a predetermined further control frequency range, and
the first and the further control frequency range are different from one another.

12. A computing device for compensating for liquid-transmitted acoustic disturbance excitations of an optical component of a lithography apparatus, said optical component being temperature-controlled using a liquid, wherein the disturbance excitations of the optical component, as a first optical component, are compensated for with the aid of a second optical component of the lithography apparatus, said second optical component not being temperature-controlled using a liquid, comprising:
a receiving unit for receiving a first and second actual value of a position corresponding to the first and second optical components, and
a controller unit for controlling the position of the second optical component to an adapted target value of the position of the second optical component, said target value being based on an initial target value of the position of the second optical component and the first actual value of the position of the first optical component.

13. A compensation system for compensating for liquid-transmitted acoustic disturbance excitations of an optical component of a lithography apparatus, said optical component being temperature-controlled using a liquid, wherein the disturbance excitations of the optical component, as a first optical component, are compensated for with the aid of a second optical component of the lithography apparatus, said second optical component not being temperature-controlled using a liquid, comprising:
the first optical component which is temperature-controlled using a liquid,
the second optical component which is not temperature-controlled using a liquid,
actuator equipment for setting a position of the second optical component, and
a computing device as claimed in claim 12 for determining a manipulated variable on the basis of a deviation of the second actual value from the adapted target value and for actuating the actuator equipment to position the second optical component on the basis of the second manipulated variable.

14. A lithography apparatus, in particular an EUV lithography apparatus, comprising a computing device as claimed in claim 12 or a compensation system for compensating for liquid-transmitted acoustic disturbance excitations of an optical component of the lithography apparatus, wherein the optical component is temperature-controlled using a liquid, wherein the disturbance excitations of the optical component, as a first optical component, are compensated for with the aid of a second optical component of the lithography apparatus, said second optical component not being temperature-controlled using a liquid, wherein the compensation system comprises:
the first optical component which is temperature-controlled using a liquid,
the second optical component which is not temperature-controlled using a liquid,
actuator equipment for setting a position of the second optical component, and
the computing device as claimed in claim 12 for determining a manipulated variable on the basis of a deviation of the second actual value from the adapted target value and for actuating the actuator equipment to position the second optical component on the basis of the second manipulated variable.

15. A method for producing controller equipment for controlling a position of an optical component of a lithography apparatus, said optical component being temperature-controlled using a liquid, comprising
determining a disturbance frequency range of acoustic disturbance excitations of the optical component, and
configuring a controller component of the controller equipment in such a way that the position of the optical component is controlled in a predetermined control frequency range which is different from the predetermined disturbance frequency range.

16. The method of claim 2, wherein controlling the position of the second optical component comprises:
determining a second manipulated variable on the basis of a second deviation of the second actual value from the adapted target value, and
actuating second actuator equipment to position the second optical component on the basis of the second manipulated variable.

17. The method of claim 2, wherein
the first and second optical components are arranged successively in relation to a beam path of the lithography apparatus,
the first and second optical components are both arranged in an imaging beam path of the lithography apparatus,
the first and second optical components are both components of a projection system of the lithography apparatus, and/or
the first and second optical components are both configured to image a mask on a substrate arranged in an image plane of the lithography apparatus and/or of the projection system of the lithography apparatus.

18. The method of claim 2, comprising
controlling a pressure of a liquid in a liquid line, which is configured to control the temperature of the first optical component using a liquid, wherein:
an actual pressure value of the pressure of the liquid is received,
a further manipulated variable is determined on the basis of a pressure deviation of the actual pressure value from a target pressure value, and
further actuator equipment of pressure-changing equipment is actuated on the basis of the determined further manipulated variable to change the pressure of the liquid in the liquid line.

19. The method of claim 3, wherein controlling the position of the second optical component comprises:
determining a second manipulated variable on the basis of a second deviation of the second actual value from the adapted target value, and
actuating second actuator equipment to position the second optical component on the basis of the second manipulated variable.

20. The method of claim 3, wherein the position of the first optical component is controlled in a first predetermined control frequency range which is different from a predetermined disturbance frequency range of the acoustic disturbance excitations of the first optical component.
